(19) United States
(12) Patent Application Publication
(10) Pub. No.: US 2009/0097165 A1
(43) Pub. Date: Apr. 16, 2009

(54) METHOD OF MANUFACTURING MAGNETIC RECORDING MEDIUM, MAGNETIC RECORDING MEDIUM AND SURFACE TREATMENT APPARATUS

(75) Inventors: Hiroshi Osawa, Chiba-shi (JP); Gohei Kurokawa, Chiba-shi (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., TOKYO (JP)

(21) Appl. No.: 11/908,254

(22) PCT Filed: Jan. 27, 2006
(86) PCT No.: PCT/JP2006/301812

§ 371 Date: Sep. 10, 2007

(30) Foreign Application Priority Data
Mar. 28, 2005 (JP) 2005-091216

(51) Int. Cl. G11B 5/33; B32B 37/00; G11B 5/64; C23C 16/54

(52) U.S. Cl. 360/314; 156/273.3; 428/800; 118/723 R; G9B/5.104

(57) ABSTRACT

The present invention provides a magnetic recording medium having superior startup operation and durability as well as satisfactory surface lubricity. The present invention relates to a method of manufacturing a magnetic recording medium in which at least a magnetic layer, a protective film layer and a lubricant layer are sequentially laminated on a non-magnetic substrate, wherein the lubricant layer is surface treated using a gas activated by plasma generated at a pressure in the vicinity of atmospheric pressure. The present invention also relates to a magnetic recording medium produced according to the aforementioned manufacturing method.

### CROSS REFERENCE TO RELATED APPLICATIONS

Priority is claimed on Japanese Patent Application No. 2005-091216, filed Mar. 28, 2005.

### TECHNICAL FIELD

The present invention relates to a magnetic recording medium used in a magnetic disk drive or other magnetic recording apparatus, and a method of manufacturing a magnetic recording medium.

### BACKGROUND ART

Hard disk drives, which are magnetic recording apparatuses used as storage apparatuses of information processing apparatuses, are provided with a magnetic head for playback and recording, and a magnetic recording medium in the form of a magnetic disk having a magnetic layer. The magnetic layer in a magnetic disk is formed by depositing a ferromagnetic metal or alloy thereof on a non-magnetic substrate by sputtering, vapor deposition or electroless plating and so forth. In general, a so-called contact start stop (CSS) method is employed in hard disk drives for recording and reproducing of data. In hard disk drives employing the CSS method, the magnetic head is in contact with the magnetic disk (to also be simply referred to as a disk) at the start of operation, and when the disk begins to rotate, the magnetic head slides over the disk, and as the rotating speed of the disk increases, the magnetic head lifts from the disk and recording and reproducing are carried out in this state. When stopping, the magnetic head again slides over the disk when the rotating speed of the magnetic disk decreases.

In magnetic disks, in order to prevent deterioration of the durability of the magnetic disk due to abrasive damage caused by sliding contact with the magnetic head, a protective film layer and a lubricant layer are provided on the magnetic layer to improve the wear resistance of the magnetic disk as well as reduce static friction and dynamic friction when the magnetic head and magnetic make sliding contact. Films such as carbon films, SiO₂, ZrO₂ and other oxide films, nitride films and boride films have typically been used for the aforementioned protective film layer. In addition, the aforementioned lubricant layer is typically formed by coating a lubricant such as a liquid perfluoropolyether compound onto the surface of the disk.

In magnetic disks, the amounts and properties of freely moving molecules in the lubricant layer along with molecules in the lubricant layer that bond to the surface of the protective film layer have an important effect on wear resistance. For example, if the amount of freely moving molecules in the lubricant layer is too great, the static friction coefficient of the disk increases, resulting in increased susceptibility to the occurrence of adsorption phenomena (so-called stiction) between the magnetic head and disk. If the amount is too low, the dynamic friction coefficient of the magnetic disk surface increases, resulting in decreased lubricity and increased susceptibility to the occurrence of the head crash.

In order to reduce stiction, the contact surface area between the head and disk is reduced by giving a certain level of roughness referred to as texturing to the disk surface, or by imparting low bumps formed by irradiating with laser light referred to as laser texturing. However, the flying height of the magnetic head over the disk has recently become extremely low at 25 nm or less in order to achieve higher recording densities. Thus, it is necessary to make the disk surface as smooth as possible and reduce the height of the bumps formed by laser texturing to avoid contact between the disk and head while driving is starting. However, when this is done, stiction conversely worsens. Since stiction cannot be adequately reduced by the bumps alone which are formed by laser texturing, it is necessary to also control the amounts and properties of freely moving molecules in the lubricant layer as well as the molecules in the lubricant layer that bond to the surface of the protective film layer as previously described.

The lubricant layer is required to enhance the bonding strength with the protective film layer accompanying increased recording density. The reasons of the requirement are indicated below. Hard disk drives are becoming increasingly compact and lightweight through the use of magnetic heads, MR elements, GMR elements and so forth for the purpose of improving recording density, and startup operation is required to be improved by lowering the static friction coefficient in order to reduce the initial drive force that also constitutes the load on the magnetic head. In order to reduce the static friction coefficient, it is effective to reduce the amount of freely moving molecules in the lubricant layer by increasing the bonding strength between the lubricant and protective film layer.

The ramp load method has also come to be used practically in recent years in addition to the CSS (Contact Start Stop) method. The lamp load method refers to a method that employs a mechanism by which a head evacuation area is provided near the outer periphery of the disk, and the head is then housed in that evacuation area when rotation of the disk is stopped. In this method, since the head does not make contact with the disk when the disk is stationary, there is said to be no concern over stiction as with the CSS method. However, it has been determined that it is necessary to reduce adsorption of the head to the disk in the ramp load method as well in order to reduce behavioral changes in the head when the head and disk inadvertently make contact. Thus, even using the ramp load method, it is important to reduce the static friction coefficient.

In addition, disk rotating speed has been increased during recording and reproducing in order to improve recording density. In the case of increasing rotating speed, a so-called spin-off phenomenon occurs in which lubricant is scattered due to centrifugal force. As a result, the problem occurs in which the film thickness of the lubricant layer decreases. It is again desirable to increase the bonding strength with the protective film layer in order to prevent spin-off and enhance durability. Furthermore, the bonded ratio is used as an indicator of the bonding strength between the lubricant and protective film layer. This value indicates the proportion (%) of lubricant that remains when a magnetic disk on which a lubricant layer has been formed is washed with a fluorine-based solvent (for example, AS225 manufactured by Asahi Glass Co., Ltd.), and provides a general reference of the bonding strength of the lubricant to the protective film layer.

Consequently, various types of treatments have been tested on the lubricant layer for the purpose of enhancing the bonding strength of the lubricant layer to the protective film layer. For example, a method is disclosed in Publication Document 1 in which heat treatment is carried out on a coated lubricant followed by ultraviolet radiation treatment. In addition, a method is disclosed in Patent Document 2 in which after a lubricant layer is formed, the lubricant layer is irradiated with ultraviolet light at a wavelength of 150 to 180 nm. In addition, a method is disclosed in Patent Document 3 in which a lubricant layer is coated onto a hydrogenated carbon protective film followed by irradiation with ultraviolet light. In addition, a method is disclosed in Patent Document 4 in which a lubricant is coated onto a carbon protective film followed by subjecting to heat treatment. In addition, a method is disclosed in J Patent Document 5 in which plasma treatment is carried out on a protective film.

However, in the methods for manufacturing magnetic recording media of the prior art in which a lubricant layer and protective film are formed by these treatment methods, it was difficult to produce a magnetic recording medium in which the bonding strength of the lubricant layer to the protective film layer was enhanced without increasing the dynamic friction coefficient. Consequently, there is a need for a magnetic recording medium having superior startup operation and durability while also obtaining adequate surface lubricity.

In consideration of the aforementioned circumstances, the object of the present invention is to obtain a magnetic recording medium having superior startup operation and durability, and satisfactory surface lubricity.

Patent Document 1: Japanese Unexamined Patent Application, First Publication No. H11-25452

Patent Document 2: Japanese Unexamined Patent Application, First Publication No. H8-124142

Patent Document 3: Japanese Unexamined Patent Application, First Publication No. H7-85461

Patent Document 4: Japanese Unexamined Patent Application, First Publication No. H5-217162

Patent Document 5: Japanese Unexamined Patent Application, First Publication No. S63-2117

### DISCLOSURE OF INVENTION

As a result of extensive studies to solve the aforementioned problems, the inventors of the present invention found that, in a manufacturing method in which a lubricant layer is surface treated using a treatment gas activated by glow discharge plasma generated under pressure in the vicinity of atmospheric pressure, it is possible to enhance the bonding strength of the lubricant to the protective film layer, lower the static friction coefficient, improve startup operation, enhance durability and obtain superior surface lubricity, thereby leading to completion of the present invention.

Namely, the present invention employs the following constitution to achieve the aforementioned object.

(1) A method of manufacturing a magnetic recording medium comprising sequentially laminating at least a magnetic layer, a protective film layer and a lubricant layer on a non-magnetic substrate, and surface treating the lubricant layer using a gas activated by plasma generated under pressure in the vicinity of atmospheric pressure;
(2) The method of manufacturing a magnetic recording medium as described in the aforementioned (1), wherein the plasma is glow discharge plasma.
(3) The method of manufacturing a magnetic recording medium as described in any of the aforementioned (1) to (2), wherein the gas contains at least one type of gas selected from the group consisting of nitrogen, oxygen and argon.
(4) The method of manufacturing a magnetic recording medium as described in any of the aforementioned (1) to (3), wherein the plasma generated under a pressure in the vicinity of atmospheric pressure is plasma generated by applying an electric field between opposing electrodes.
(5) The method of manufacturing a magnetic recording medium as described in the aforementioned (4), wherein the opposing electrodes are arranged at an angle of 1 degree to 45 degrees from perpendicular to a treated substrate in which at least the magnetic layer, the protective film layer and lubricant layer are formed on the non-magnetic substrate.
(6) The method of manufacturing a magnetic recording medium as described in the aforementioned (4), wherein the opposing electrodes are formed perpendicular to a treated substrate in which at least the magnetic layer, the protective film and the lubricant layer are formed on the non-magnetic substrate.
(7) The method of manufacturing a magnetic recording medium as described in the aforementioned (4), wherein surface treatment is carried out on the lubricant layer by arranging a treated substrate, in which at least the magnetic layer, the protective film and the lubricant film layer are formed on the non-magnetic substrate, between the opposing electrodes.
(8) The method of manufacturing a magnetic recording medium as described in any of the aforementioned (1) to (7), wherein surface treatment using the activated gas is simultaneously carried out on both sides of a treated substrate in which at least a magnetic layer, a protective film layer and a lubricant layer are formed on the non-magnetic substrate.
(9) The method of manufacturing a magnetic recording medium as described in any of the aforementioned (1) to (8), wherein the non-magnetic substrate is one type of substrate selected from a glass substrate and a silicon substrate.
(10) The method of manufacturing a magnetic recording medium as described in any of the aforementioned (1) to (8), wherein the non-magnetic substrate has a film comprised of NiP or NiP alloy formed on the surface of a base comprised of one type of material selected from Al, Al alloy, glass and silicon.
(11) A magnetic recording medium produced according to the method of manufacturing a magnetic recording medium as described in any of the aforementioned (1) to (10).
(12) A magnetic recording and reproducing device provided with a magnetic recording medium and a magnetic head that records and reproduces data onto said magnetic recording medium; wherein, the magnetic recording medium is the magnetic recording medium as described in the aforementioned (11).
(13) A surface treatment apparatus that has a first device for forming an activated gas by generating plasma by applying an electric field between opposing electrodes under pressure in the vicinity of atmospheric pressure, and a second device for radiating the activated gas onto the surface of a treated substrate in which at least a magnetic layer, the protective film and a lubricant layer are formed on a non-magnetic substrate.

The invention of the present application is similar to Japanese Unexamined Patent Application, Publication No. S63-2117 in which plasma is used to improve the surface characteristics of the protective film. However, in contrast to the technology described in Japanese Unexamined Patent Application, First Publication No. S63-2117 carrying out plasma treatment in a vacuum, the invention of the present application is quite different in that plasma treatment is carried out at a pressure in the vicinity of atmospheric pressure. If plasma treatment is carried out in a vacuum, since the activated treatment gas contacts the surface of the protective film without losing hardly any of its activity, a portion of the protective film itself ends up being etched. On the other hand, if treatment gas is used that has been treated with plasma at a pressure in the vicinity of atmospheric pressure, its activity decreases due to the frequent occurrence of collisions between its molecules due to its extremely high molecular density, thereby making it suitable for surface treatment of the lubricant film. In addition, the vacuum device used for plasma treatment in a vacuum is large due to comprising components such as a vacuum chamber, exhaust pump and transport system for transporting from atmospheric pressure to a vacuum, and also ends up being expensive. On the other hand, in the case of treating with plasma at a pressure in the vicinity of atmospheric pressure, vacuum equipment is not required, making it possible to achieve simplification of the apparatus and reduced costs.

### BRIEF DESCRIPTION OF THE DRAWINGS

FIG. 1 is a cross-sectional view showing one embodiment of a magnetic recording medium of the present invention.

FIG. 2 is a schematic block drawing showing one embodiment of a plasma generation unit used to produce a magnetic recording medium of the present invention.

FIG. 3 is a schematic block drawing showing another embodiment of a plasma generation unit used to produce a magnetic recording medium of the present invention.

FIG. 4 is a schematic block drawing showing another embodiment of a plasma generation unit used to produce a magnetic recording medium of the present invention.

FIG. 5 is a schematic block drawing showing another embodiment of a plasma generation unit used to produce a magnetic recording medium of the present invention.

FIG. 6 is a schematic block drawing showing another embodiment of a plasma generation unit used to produce a magnetic recording medium of the present invention.

### BEST MODE FOR CARRYING OUT THE INVENTION

The following provides an explanation of embodiments of the present invention with reference to the drawings.

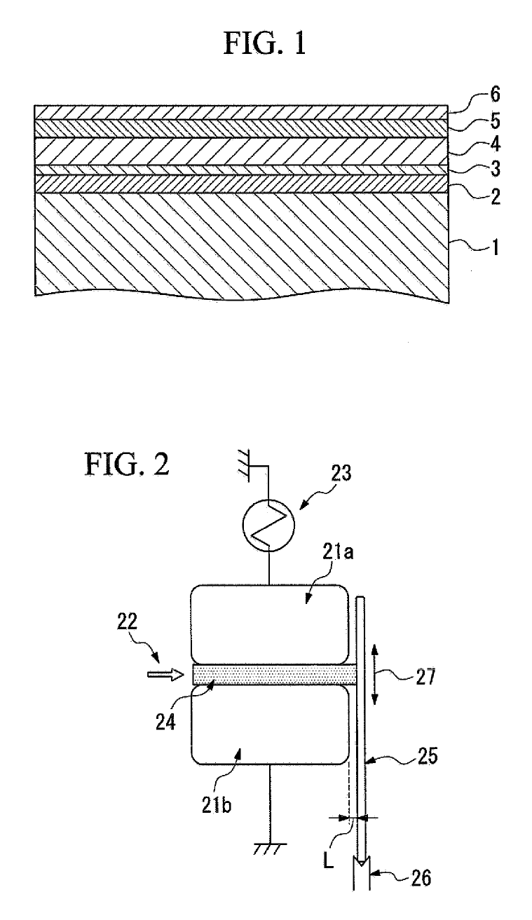

FIG. 1 is a cross-sectional view showing one embodiment of a magnetic recording medium of the present invention.

A magnetic recording medium of the present embodiment is composed by sequentially laminating a substrate layer 2, an intermediate layer 3, a magnetic layer 4 and a protective film layer 5 on a non-magnetic substrate 1, and providing a lubricant layer 6 on the uppermost layer.

Examples of materials that can be used for non-magnetic substrate 1 include metal materials such as aluminum and aluminum alloy, inorganic materials such as glass, ceramics, titanium, carbon and silicon, and polymer compounds such as polyethylene terephthalate, polyimide, polyamide, polycarbonate, polysulfone, polyethylene naphthalate, polyvinyl chloride and cyclic hydrocarbon-containing polyolefin. In addition, one or more types of films selected from NiP, NiP alloy and other alloys can be vapor deposited by plating or sputtering and so forth onto the surfaces of these substrates.

The material of substrate layer 2 can be composed with Cr or Cr alloy composed of Cr and one or more types of metals selected from Ti, Mo, Al, Ta, W, Ni, B, Si, Mn and V.

In the case of substrate layer 2 being a non-magnetic substrate layer having a multilayered structure, at least one of the constituent layers that compose the non-magnetic substrate layer can be composed with the aforementioned Cr alloy or Cr.

The aforementioned non-magnetic substrate layer can also be composed with an NiAl-based alloy, RuAl-based alloy or Cr alloy (alloy composed of Cr and one or more types selected from Ti, Mo, Al, Ta, W, Ni, B, Si and V).

In the case that the non-magnetic substrate layer has a multilayered structure, at least one of the constituent layers that compose the non-magnetic substrate layer can be composed with an NiAl-based alloy, RuAl-based alloy or the aforementioned Cr alloy.

The material of intermediate layer 3 is used for the purpose of assisting the epitaxial growth of Co alloy of magnetic layer 4, and is preferably a non-magnetic material having an hcp structure. The material of intermediate layer 3 is a Co alloy having Co as its main raw material. Preferable examples include materials containing any one type selected from Co—Cr-based alloy, Co—Cr—Ru-based alloy, Co—Cr—Ta-based alloy and Co—Cr—Zr-based alloy.

The material of magnetic layer 4 which preferably has an hcp structure is a Co alloy having Co as its main raw material. Preferable examples include materials containing any one type selected from Co—Cr—Ta-based alloy, Co—Cr—Pt-based alloy, Co—Cr—Pt—Ta-based alloy, Co—Cr—Pt—B-based alloy and Co—Cr—Pt—B—Cu-based alloy.

A carbon-based material such as amorphous carbon, hydrogen-containing carbon and fluorine-containing carbon, or a ceramic-based material such as silica and zirconia can be used for protective film layer 5. In particular, hard and dense CVD carbon is used preferably in terms of not only its durability, but also its economy and productivity. In order to improve the durability of the protective film layer and at the same time to decrease the loss during recording and reproducing, the film thickness of protective film layer 5 is set to 10 to 150 Å (1 to 15 nm), and preferably set to 20 to 60 Å (2 to 6 nm).

The uppermost lubricant layer 6 contains a polymer of a polymerizeable unsaturated group-containing perfluoropolyether compound. An example of polymerizeable unsaturated group-containing perfluoropolyether compounds is a compound having perfluoropolyether serving as the main chain, at least one end of which is bonded with an organic group having a polymerizeable unsaturated bond.

Lubricant layer 6 is subjected to surface treatment using a gas (treatment gas) activated by plasma to be described later.

A magnetic recording and reproducing device of the present embodiment is provided with the aforementioned magnetic recording medium having lubricant layer 6 on which surface treatment has been carried out with the aforementioned treatment gas, and a magnetic head that records and reproduces information on said magnetic recording medium.

Next, the following provides an explanation of an example of a method of manufacturing a magnetic recording medium of the present embodiment.

First, after forming substrate layer 2, intermediate layer 3, magnetic layer 4 and protective film layer 5, a lubricant layer is formed on non-magnetic substrate 1, surface treatment is performed on this lubricant layer using a gas that has been activated by plasma generated under pressure in the vicinity of atmospheric pressure to form lubricant layer 6. The aforementioned plasma is preferably glow discharge plasma.

A plasma generation unit capable of stable generation of plasma at a pressure in the vicinity of atmospheric pressure, can be used for the surface treatment apparatus used here for surface treatment. Examples of apparatuses that can be used include a normal-pressure plasma surface modification apparatus (Sekisui Chemical, Co.) and an atmospheric pressure plasma cleaning head (Matsushita Electric Works).

A pressure in the vicinity of atmospheric pressure refers to pressure of 1.3×10⁴ to 13×10⁴ Pa. In particular, the use of a pressure in the vicinity of atmospheric pressure of 9.9×10⁴ to 10.3×10⁴ Pa is preferable since it facilitates pressure regulation and simplifies the apparatus constitution.

The following provides an explanation of a plasma generation unit of the present embodiment using FIG. 2.

The plasma generation unit of FIG. 2 is primarily composed by a pair of opposing electrode plates (opposing electrodes) 21a and 21b, a gas inlet port 22 for supplying gas between electrode plates 21a and 21b, a plasma generation power supply 23 that applies an electric field between the opposing electrodes, and a substrate holder 26 for holding a treated substrate 25.

This plasma generation unit of FIG. 2 has a first device for forming a gas that has been activated by generating plasma by applying an electric field between the pair of opposing electrode plates 21a and 21b at a pressure in the vicinity of atmospheric pressure, and a second device for radiating the activated gas onto the surface of treated substrate 25.

Treated substrate 25 has at least a magnetic layer, a protective film layer and a lubricant layer prior to surface treatment formed on a non-magnetic substrate, and in the case of the present embodiment, has a substrate layer 2, intermediate layer 3, magnetic layer 4 and a lubricant layer prior to surface treatment formed on a non-magnetic substrate 1.

Iron, copper, aluminum or alloys thereof is used for the material of each electrode plate 21a or 21b. Although the distance between the opposing electrodes is preferably 0.1 to 50 mm, it is more preferably 0.1 to 5 mm in consideration of the stability of plasma discharge.

A pulse wave, a high-frequency wave or a microwave is used for the electric field impressed between electrode plates 21a and 21b. The pulse wave that can adjust the impression time of electric field, is preferable. It is preferable to use the pulse wave at the frequency of 1 to 500 kHz, especially, 1 to 50 kHz, in consideration of stability of the plasma discharge. It is preferable that the impression time of electric field namely duration of the pulse wave is from 0.5 to 200 μsec. When it is under the 0.5 μsec, plasma discharge does not occur. When it exceeds 200 μsec, it is become easy to form arc.

Nitrogen, oxygen, argon or a mixture thereof is preferably used for the gas supplied between electrode plates 21a and 21b. Since the amount of gas consumed is large due to using at a pressure in the vicinity of atmospheric pressure, inexpensive nitrogen, oxygen or a mixed gas of nitrogen and oxygen is used more preferably.

In FIG. 2, a pair of electrode plates 21a and 21b is arranged perpendicular to a lubricant layer prior to surface treatment (treated substrate 25). Although plasma is generated between the electrodes, since the generated plasma spreads out, a plasma state is also generated at portions where the plasma spills out from between the electrodes. The distance from one end of the opposing electrode plates to the lubricant layer (treated substrate 25) is preferably 0.1 to 5 mm. If this distance is less than 0.1 mm, there is the risk of treated substrate 25 being crushed by the electrode plates, thus making this undesirable. If this distance exceeds 5 mm, since the plasma spreads excessively causing effects to decrease considerably, surface treatment effects are not obtained. Gas supplied between the pair of electrode plates 21a and 21b under pressure in the vicinity of atmospheric pressure becomes treatment gas as a result of being activated by plasma generated between these electrodes, and since this treatment gas has an extremely high molecular density, activity decreases due to the frequent occurrence of collisions between molecules, thereby making it suitable for surface treatment of a lubricant film.

It is preferable to use a transport method that does not contact both surfaces of the substrate in order to use both sides of a magnetic recording medium (magnetic disk). Thus, it is preferable to transport treated substrate 25 by holding onto the inside edge or outside edge. The transport speed is preferably 10 to 2000 mm/minute. A transport speed of 100 to 1000 mm/minute is more preferable in consideration of high throughput and surface treatment effects. The transport method may consist of moving treated substrate 25 or moving the plasma generation unit. An example of a transport method that moves treated substrate 25 consists of moving treated substrate 25 by using a substrate holder 26 that has a function that enables it to be raised and lowered to sequentially treat the surface of the protective film layer with treatment gas.

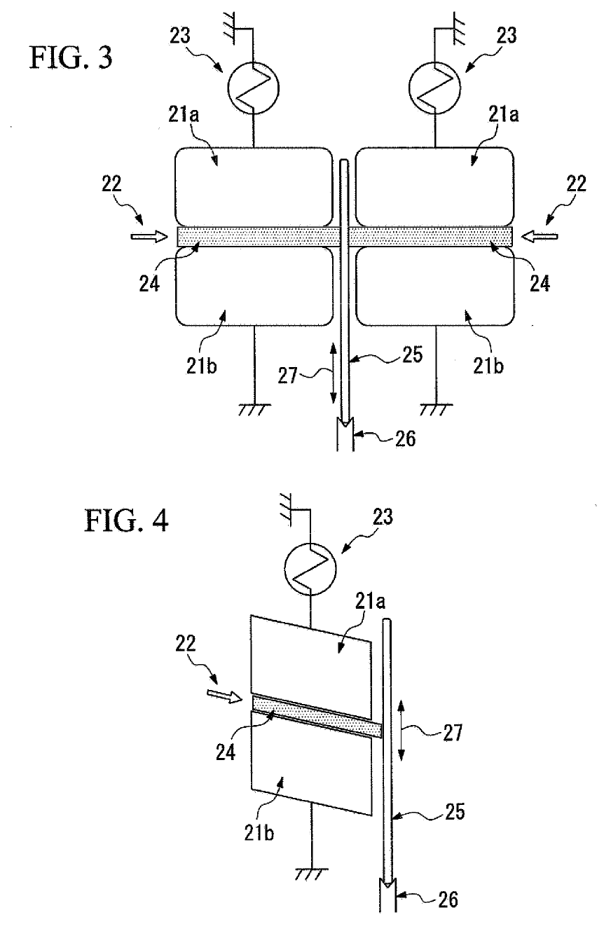

As shown in FIG. 3, in order to use both sides of a magnetic recording medium, it is preferable to arrange plasma generation units on both sides of treated substrate 25 as previously described, and carry out surface treatment using a gas activated by plasma generated at a pressure in the vicinity of atmospheric pressure on both sides of treated substrate 25.

In the case of transporting by holding onto an inside edge or outside edge of treated substrate 25, the inside edge or outside edge of treated substrate 25 ends up being concealed by the shadow of holder 26, resulting in the risk of a decrease in surface treatment effects at the concealed locations. In order to prevent this, it is preferable that the opposing pair of electrode plates 21a and 21b be arranged inclined at an angle of 1 to 45 degrees from perpendicular with respect to the protective film layer prior to surface treatment (treated substrate 25) as shown in FIG. 4. Furthermore, FIG. 4 shows an example of an apparatus in the case of transporting treated substrate 25 by holding onto its outside edge.

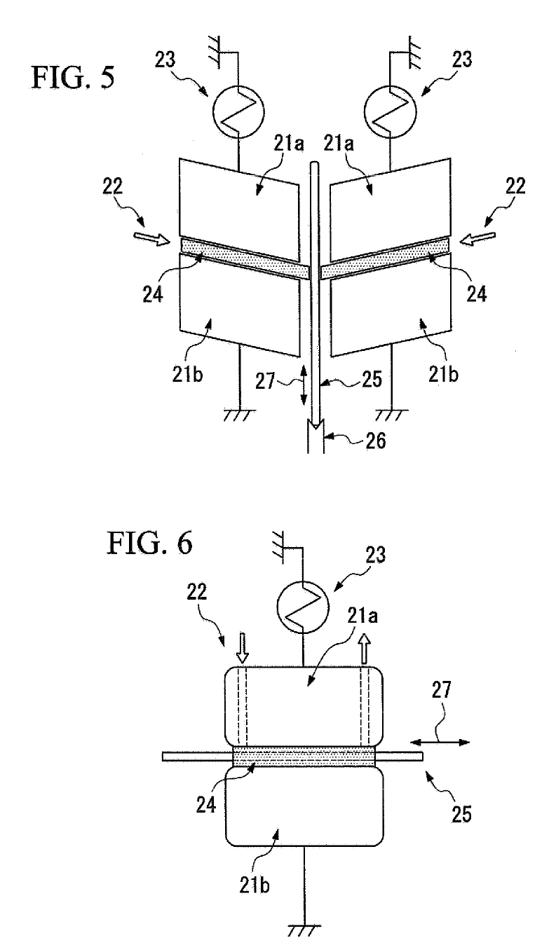

If surface treatment is carried out by arranging the pair of opposing electrode plates 21a and 21b inclined at an angle of 1 to 45 degrees from perpendicular with respect to treated substrate 25, since the plasma is irradiated on an incline with respect to the protective film, treatment gas activated by plasma also contacts the portion concealed by the shadow of holder 26. In this case as well, it is preferable to arrange plasma generation units on both sides of treated substrate 25 as shown in FIG. 5.

A protective film layer of treated substrate 25 can also be surface treated by passing treated substrate 25 between the pair of opposing electrode plates 21a and 21b as shown in FIG. 6. In this case, more powerful surface treatment can be carried out since the plasma density is higher.

Furthermore, in FIGS. 2 to 6, mark 27 is a traveling direction (movement direction) of the processing substrate 25.

### EXAMPLES

After adequately washing and drying an aluminum alloy substrate having an Nip plated film (diameter: 95 mm, inner diameter: 25 mm, thickness: 1.27 mm), it was irradiated with a laser from a radius of 17 mm to 19 mm (CSS zone) to form bumps having a height of 10 nm. Subsequently, the substrate was placed in a DC Magnetron Sputtering System (Model C3010, Anelva). After evacuating the air to an attainable vacuum of 2×10⁻⁷ Torr (2.7×10⁻⁵ Pa), the substrate was heated to 250° C.

Following heating, a non-magnetic substrate layer was laminated to a thickness of 5 nm using a target composed of Cr. Moreover, a non-magnetic substrate layer was laminated to a thickness of 5 nm using a target composed of Cr—Mo alloy (Cr: 80 at %, Mo: 20 at %). Next, a non-magnetic intermediate layer was laminated to a thickness of 2 nm using a target composed of Co—Cr alloy (Co: 65 at %, Cr: 35 at %). Next, a magnetic layer in the form of a CoCrPtB alloy layer was formed as a magnetic layer at a film thickness of 20 nm using a target composed of Co—Cr—Pt—B alloy (Co: 60 at %, Cr: 22 at %, Pt: 12 at %, B: 6 at %), and a protective film composed of CVD carbon was laminated to a thickness of 5 nm using a plasma CVD system to obtain a treated substrate. The argon pressure during film deposition was set to 3 mTorr (0.4 Pa).

After deposition of the protective film, the substrate was removed from the vacuum system, a lubricant composed of perfluoropolyether was coated onto the protective film layer at a pulling rate of 3 mm/sec by a dipping method after adjusting to 0.05% by weight to obtain a magnetic disk (sample). The fluorine-based solvent AK225 (Asahi Glass) was used as the solvent at this time.

Subsequently, the lubricant film surface of the substrate was surface treated in the manner shown in FIG. 2 using a normal pressure plasma surface modification unit (Sekisui Chemical Co.) for the plasma generation unit. The transport speed, N₂ flow rate, O₂ flow rate, and distance from one end of the opposing electrodes (end nearest the treated substrate) to the lubricant film on the treated substrate were changed as shown in Table 1. Furthermore, a sample was produced in the same manner as the aforementioned method with the exception of not carrying out the aforementioned surface treatment on the protective film layer for the sake of comparison. This is Comparative Example 1.

The lubricant film thicknesses of each of the samples produced were measured using FTIR. Those results are shown in Table 1. In addition, bonded ratio was measured in the manner described below to serve as an indicator of bonding strength of the lubricant layer to the protective film layer. After washing the surface of the aforementioned magnetic disk by immersing in fluorine-based solvent AK225 (Asahi Glass) for 15 minutes, the thicknesses of the lubricant layer before and after washing were measured using FTIR at a location at a radius of 20 mm, and the thickness of the lubricant layer after washing versus the lubricant layer thickness before washing was taken to be the bonded ratio (%). The results are shown in Table 1.

Dynamic friction coefficients were also measured. A CSS (Contact Start Stop) durability test was carried out under conditions of a temperature of 25° and humidity of 60% RH. In this test, 10000 CSS operations (consisting of rotating at a rotating speed of 10000 rpm (maintained for 1 second) and stopping (1 second), and repeating at 5 second intervals) were carried out in the CSS zone using a CSS tester and a reference MR head (DLC coating, 30% slider, load: 2.5 g) for the magnetic head. The dynamic friction coefficients of the magnetic disk surface after 10,000 CSS operations are shown in Table 1.

Static friction coefficients were also measured. A CSS (Contact Start Stop) durability test was carried out under conditions of a temperature of 40° and humidity of 80% RH. In this test, 10000 times CSS operations (consisting of rotating at a rotating speed of 10000 rpm (maintained for 1 second) and stopping (1 second), and repeating at 5 second intervals) were carried out in the CSS zone using a CSS tester and a reference MR head (DLC coating, 30% slider, load: 2.5 g) for the magnetic head. The static friction coefficients of the magnetic disk surface after 10,000 CSS operations are shown in Table 1.

Film thickness reduction rates were also measured (spin-off test). The magnetic disk was rotated for 72 hours in an environment at 80° C. and at a rotating speed of 10000 rpm. The thickness of the lubricant layer at a location at a radius of 20 mm was measured before and after this operation, and the reduction rates of film thickness of the lubricant layer before and after testing were measured with FTIR. The results are shown in Table 1.

Furthermore, although the units of the values shown for lubricant film thickness are in angstroms, they can be converted to nanometers by multiplying 0.1 by the values shown for lubricant film thickness in the table.

TABLE 1

| | Transport | N₂ Flow | O₂ Flow | | | Bonded | Dynamic | Static | |
|---|---|---|---|---|---|---|---|---|---|
| | Speed | Rate | Rate | D*¹ | t*² | Ratio | Friction | Friction | R*³ |
| | mm/min | l/min | l/min | mm | Å | % | Coeff. | Coeff. | % |
| Ex. 1 | 100 | 40 | 0 | 2 | 16.5 | 72 | 0.36 | 0.41 | 2 |
| Ex. 2 | 300 | 40 | 0 | 2 | 16.4 | 73 | 0.35 | 0.42 | 3 |
| Ex. 3 | 600 | 40 | 0 | 2 | 16.7 | 70 | 0.38 | 0.4 | 4 |
| Ex. 4 | 1000 | 40 | 0 | 2 | 16.6 | 71 | 0.38 | 0.44 | 5 |
| Ex. 5 | 2000 | 40 | 0 | 2 | 17.4 | 48 | 0.33 | 0.81 | 10 |
| Ex. 6 | 600 | 40 | 0 | 1 | 16.6 | 74 | 0.36 | 0.45 | 4 |
| Ex. 7 | 600 | 40 | 0 | 3 | 16.7 | 72 | 0.34 | 0.51 | 3 |
| Ex. 8 | 600 | 40 | 0 | 5 | 16.5 | 54 | 0.36 | 0.88 | 9 |
| Ex. 9 | 600 | 40 | 0 | 10 | 17.5 | 42 | 0.31 | 1.21 | 19 |
| Ex. 10 | 600 | 1 | 0 | 2 | 17.3 | 47 | 0.33 | 0.81 | 13 |
| Ex. 11 | 600 | 10 | 0 | 2 | 16.4 | 72 | 0.35 | 0.41 | 2 |
| Ex. 12 | 600 | 20 | 0 | 2 | 16.3 | 74 | 0.35 | 0.43 | 4 |
| Ex. 13 | 600 | 100 | 0 | 2 | 16.7 | 71 | 0.36 | 0.48 | 3 |
| Ex. 14 | 600 | 200 | 0 | 2 | 16.8 | 73 | 0.38 | 0.43 | 4 |
| Ex. 15 | 600 | 40 | 5 | 2 | 16.5 | 72 | 0.37 | 0.47 | 3 |
| Ex. 16 | 600 | 40 | 20 | 2 | 16.7 | 69 | 0.36 | 0.48 | 3 |
| Ex. 17 | 600 | 40 | 40 | 2 | 16.9 | 73 | 0.35 | 0.42 | 4 |

| | | | | | | |
|---|---|---|---|---|---|---|
| Comp. Ex. 1 | No Plasma Treatment | 17.2 | 40 | 0.28 | 1.32 | 17 |

*¹D, Distance from Opposing Electrode End to Lubricant Film
*²t, Thickness of Lubricant Film
*³R, Ratio of Film Thickness Reduction

As can be seen from the results shown in Table 1, the bonded ratios improved considerably from 40% (Comparative Example 1) to 72% (Example 1). This means that the number of freely moving molecules of the lubricant decreased, and as a result, the static friction coefficients improved considerably from 1.32 (Comparative Example 1) to 0.41 (Example 1), and the film thickness reduction rates as determined from the spin-off test also improved considerably from 17% (Comparative Example 1) to 2% (Example 1). Furthermore, in the comparative examples, the effects of surface treatment were not observed if the distance from one end of the opposing electrodes to the lubricant layer is 10 mm.

On the basis of the above results, as a result of carrying out plasma surface treatment using a normal pressure plasma surface modification unit on a lubricant layer at a pressure in the vicinity of atmospheric pressure, adhesion of lubricant was observed to improve. As a result, not only can the static friction coefficient be adequately lowered, startup operation improved and durability enhanced by preventing spin-off phenomenon, satisfactory surface lubricating characteristics can also be obtained.

### INDUSTRIAL APPLICABILITY

According to the method of manufacturing a magnetic recording medium of the present invention, a magnetic recording medium can be produced that has superior startup operation and durability, and satisfactory surface lubricity characteristics.

A magnetic recording medium of the present invention has superior startup operation and durability, and satisfactory surface lubricity characteristics.

1. A method of manufacturing a magnetic recording medium comprising:
sequentially laminating at least a magnetic layer, a protective film layer and a lubricant layer, on a non-magnetic substrate; and
treating a surface of the lubricant layer using a gas activated by plasma generated under pressure in a vicinity of atmospheric pressure.

2. The method of manufacturing a magnetic recording medium according to claim 1, wherein the pressure of the surface treatment is from 1.3×10⁴ to 13×10⁴ Pa.

3. The method of manufacturing a magnetic recording medium according to claim 1, wherein the pressure of the surface treatment is from 9.9×10⁴ to 10.3×10⁴ Pa.

4. The method of manufacturing a magnetic recording medium according to claim 1, wherein the plasma is glow discharge plasma.

5. The method of manufacturing a magnetic recording medium according to claim 1, wherein the gas contains at least one type of gas selected from a group consisting of nitrogen, oxygen and argon.

6. The method of manufacturing a magnetic recording medium according to claim 1, wherein the plasma generated under pressure in a vicinity of the atmospheric pressure is a plasma generated by applying an electric field between opposing electrodes.

7. The method of manufacturing a magnetic recording medium according to claim 6, wherein the opposing electrodes are arranged at an angle of 1 degree to 45 degrees from perpendicular to a substrate to be treated in which at least a magnetic layer, a protective film layer and a lubricant layer are formed on the non-magnetic substrate.

8. The method of manufacturing a magnetic recording medium according to claim 6, wherein the opposing electrodes are formed perpendicular to a substrate to be treated in which at least a magnetic layer, a protective film layer and a lubricant layer are formed on the non-magnetic substrate.

9. The method of manufacturing a magnetic recording medium according to claim 6, wherein surface treatment is carried out on the protective film layer by arranging a substrate to be treated, in which at least a magnetic layer, a protective film layer and a lubricant layer are formed on the non-magnetic substrate, between the opposing electrodes.

10. The method of manufacturing a magnetic recording medium according to claim 1, wherein surface treatment using the activated gas is simultaneously carried out on both sides of a substrate to be treated in which at least a magnetic layer, a protective film layer and a lubricant layer are formed on the non-magnetic substrate.

11. The method of manufacturing a magnetic recording medium according to claim 1, wherein the non-magnetic substrate is one type of substrate selected from a glass substrate and a silicon substrate.

12. The method of manufacturing a magnetic recording medium according to claim 1, wherein the non-magnetic substrate has a film comprised of NiP or NiP alloy formed on the surface of a base comprised of one type of material selected from Al, Al alloy, glass and silicon.

13. A magnetic recording medium manufactured by the method of manufacturing a magnetic recording medium according to claim 1.

14. A magnetic recording and reproducing device comprising:
the magnetic recording medium according to claim 13; and
a magnetic head that records and reproduces data onto the magnetic recording medium.

15. A surface treatment apparatus comprising:
a first device for forming an activated gas by generating plasma by applying an electric field between opposing electrodes under pressure in a vicinity of atmospheric pressure; and
a second device for radiating the activated gas onto surface of a substrate to be treated in which at least a magnetic layer, a protective film layer and a lubricant layer are formed on a non-magnetic substrate.
